(19) United States
(12) Patent Application Publication
(10) Pub. No.: US 2026/0086171 A1
(43) Pub. Date: Mar. 26, 2026

(54) REGISTRATION AND LIFE CYCLE MANAGEMENT OF DISTRIBUTED ENERGY RESOURCE DEVICES

(71) Applicant: Itron, Inc., Liberty Lake, WA (US)

(72) Inventors: Richard Wallbrink, Victoria (AU); Howard Ng, Towaco, NJ (US); Thomas Kring, Concord, CA (US)

(21) Appl. No.: 19/195,434

(22) Filed: Apr. 30, 2025

Related U.S. Application Data
(60) Provisional application No. 63/697,303, filed on Sep. 20, 2024.
(60) Provisional application No. 63/703,368, filed on Oct. 4, 2024.

(51) Int. Cl. G01R 31/56

(52) U.S. Cl. CPC G01R 31/56

(57) ABSTRACT

A method and system for testing an electrical device in an energy system are provided. The method includes: selecting a test suite to run against the electrical device based on a type of the electrical device; in response to determining that an output power of the electrical device is greater than a preselected minimum threshold: determining that the electrical device is energized, and running the test suite; in response to determining that the electrical device has passed the test suite: attaching the electrical device to a designated service point in a topology structure, marking a state of the electrical device to active, and activating the electrical device in the energy system; and in response to determining that the electrical device has not passed the test suite: attaching the electrical device to a limited node in the topology structure, and limiting the electrical device to function within a default control limit.

This patent application claims benefit of priority to U.S. provisional patent application Ser. No. 63/697,303, titled “AUTOMATED COMPLIANCE TESTING OF DISTRIBUTED ENERGY RESOURCE DEVICES”, filed on Sep. 20, 2024, and to U.S. provisional patent application Ser. No. 63/703,368, titled “REGISTRATION AND LIFE CYCLE MANAGEMENT OF DISTRIBUTED ENERGY RESOURCE DEVICES”, filed on Oct. 4, 2024, which are incorporated herein by reference.

### TECHNICAL FIELD

The present disclosure generally relates to the field of testing an electrical device and registering the electrical device, and more specifically to automatically testing an electrical device, such as a distributed energy resource (DER) device, in response to detecting an event under real conditions and registering the electrical device upon passing the testing.

### BACKGROUND

As a part of an initial registration of a client, or an electrical device, a utility provider of a grid, to which the electrical device is attached or installed, needs to perform a set of compliance tests to ensure that the electrical device operates properly within the grid. When an electrical device is tested, it is often tested with testing equipment designed to simulate the working environment and/or conditions associated with actual use in the field. Testing may encompass a wide range of variables, such as temperature, humidity, signal strength, signal noise, communication interference, communication interface connection protocols, mounting positions, interfacing devices, etc. However, it is difficult to simulate, or anticipate, all potential variables involved in setting up, or installing an electrical device in the field. The electrical device may be a distributed energy resource (DER) device. By way of example, distributed energy resource devices may include monitors, meters, cameras, solar inverters, electric vehicle chargers, wind turbines, batteries, or any other device that provides energy generation and/or storage. Such electrical devices may perform various functions, such as monitoring certain parameters, storing, analyzing, transmitting, and/or receiving data to and/or from other devices via one or more wired and/or wireless communication networks using various protocols, and interacting with various external devices, components, and equipment. To perform properly, devices intended for communicating with the electrical device must be compatible with the electrical device. For example, while the electrical device itself has passed all the testing in a laboratory or factory setup, the electrical device may still not be able to function properly if, based upon the following situations, other devices in communication with, or connected to, the electrical device are running operating systems untested with the electrical device; the communication link between the devices is faulty or unreliable due to aspects of the local geography; a technician installing and setting up the electrical device has not properly followed the recommended procedures; some connections to the electrical device have not been made properly; someone or something has tampered with the electrical device; another device in the area is interfering with communications with the device; etc.

The electrical device must be online and energized before the compliance testing can be initiated. However, in some instances, there may be an expected period of one day to 14 days or so between an installer completing the installation of the electrical device at a customer's site and an inspector performing an inspection, providing approval, and energizing the electrical device.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features. Moreover, the figures are intended to illustrate general concepts, and not to indicate required and/or necessary elements.

FIG. 1 illustrates an example client test suite (CTS) system.

FIG. 2 illustrates a flowchart of an example installation and commissioning process of a distributed energy resource (DER) device.

FIG. 3 illustrates a first portion of a flowchart of an example process of testing an electrical device utilizing a client test suite (CTS) designed for the client.

FIG. 4 illustrates a second portion of the flowchart of the example process of testing the electrical device utilizing the CTS designed for the client.

FIG. 5 illustrates a third portion of the flowchart of the example process of testing the electrical device utilizing the CTS designed for the client.

FIG. 6 illustrates a flowchart of an example automatic process of testing the electrical device utilizing the CTS.

FIG. 7 illustrates an example logical topology structure provided by a utility server of the CTS system.

### DETAILED DESCRIPTION

A client test suite (CTS) is specifically designed to evaluate functionality of commands compliant with requirements of a specific client for interoperability of devices associated with the specific client. The CTS is an application that performs device compliance testing and, in some examples, utilizes: an inbound application programming interface (API) call to trigger test runs (start and stop); an outbound API call to push test case reports to a utility backend or a distributed energy resource management system (DERMS); user interface (UI) to configure test cases, test suites, and test options, and to query and view test results and history; and a test engine to execute test runs of predefined test cases and interface with a utility server. The CTS may include one or more tests that cover a wide range of functionalities, including but not limited to:
Registration: tests for successful device registration with a utility server, including verification of authentication and authorization processes,
Monitoring: evaluates the accuracy and timeliness of data transmission from the distributed energy resource (DER) to the utility server, encompassing various data points like real-time power output, inverter status, and historical data retrieval,
Emergency curtailment: assesses the DER's response to emergency curtailment signals sent by the utility server, ensuring proper power reduction during critical events,
Control management: validates the DER's ability to receive and execute control commands from the utility server, such as active power control and setpoint adjustments, and/or
Additional functionalities: depending on the specific capabilities of the DER system being tested, the CTS may encompass additional functionalities as outlined in relevant industry standards.

The list of tests provided above is merely one example and in other examples the CTS may be configured to run additional and/or alternative tests. By incorporating a comprehensive set of tests, a self-contained resource for comprehensive command testing for a utility provider, such as the specific client, may be created, which ensures a standardized and thorough evaluation process, promoting interoperability and reliable communication within an energy or electrical grid of the specific client. A configurable test suite, such as the CTS, may execute pre-defined tests and analyze the results of the pre-defined tests. Additionally, the CTS can be updated to create and manage new tests as new devices are introduced, new software or firmware is introduced, and/or as new performance scenarios arise.

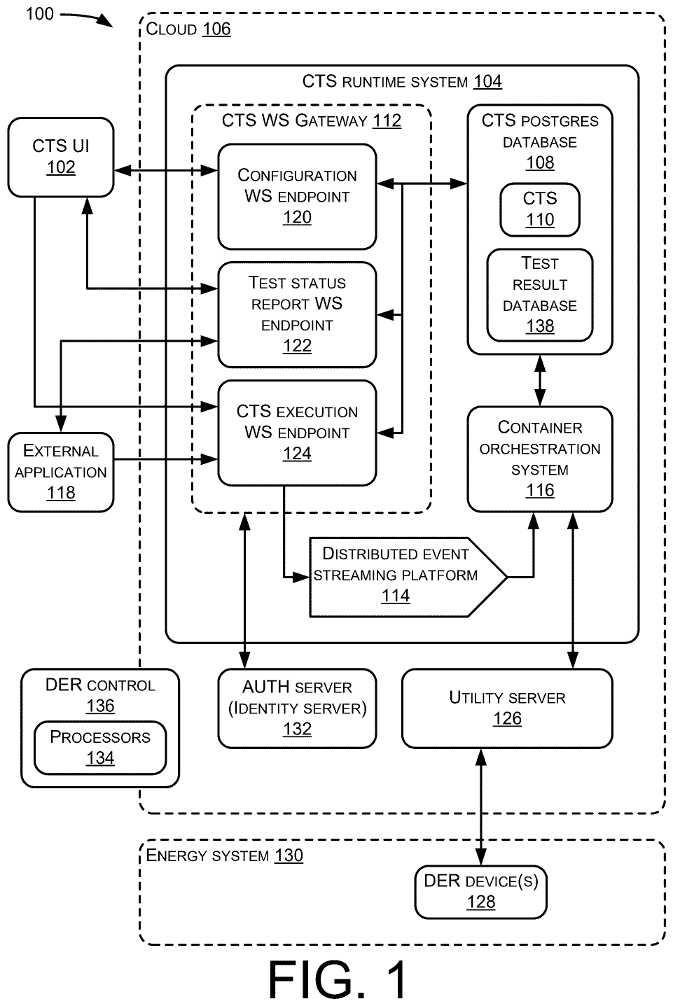

FIG. 1 illustrates an example CTS system 100 including a CTS user interface (UI) 102 and a CTS runtime system 104. The CTS UI 102, which may be hosted within or outside a cloud 106, is the primary means of creating and editing test suites. The CTS UI 102 may receive inputs from a user and provide outputs from the CTS runtime system 104. For example, the CTS UI 102 may receive instructions or commands from an installer of an electrical device to be tested and may display results and/or status associated with testing the electrical device. The CTS runtime system 104, which may be hosted in the cloud 106, may support multiple tenants as further described below. The CTS runtime system 104 may include and support one or more of: a CTS postgres database 108 storing the CTS 110, a CTS web service (WS) gateway 112, a distributed event streaming platform 114, such as a Kafka platform that is an open source, distributed streaming platform, and a container orchestration system 116, such as a Kubernetes system that is an open source software system. The CTS WS gateway 112 may interact with, and/or be utilized by, the CTS UI 102 and other external applications 118, and may include a configuration WS endpoint 120 for creating, editing, and/or updating the CTS, a test status report WS endpoint 122 for overviewing CTS execution history and tracking the status of the CTS 110, and a CTS execution WS endpoint 124 for queuing a targeted test suite, such as the one or more tests included in the CTS 110, for execution into the distributed event streaming platform 114. Once the CTS 110 is queued, the CTS execution WS endpoint 124 sends all OK response to the CTS UI 102.

The CTS runtime system 104 may dequeue the CTS from the distributed event streaming platform 114 and start executing the CTS in defined steps using defined parameters and aiming at a specified utility server, such as a utility server 126, to execute the CTS. In case the same device is subject to multiple tests included in the CTS, all tests that come in while there is a pending or active test in progress may be rejected by the CTS execution WS endpoint 124 to prevent tests running in parallel from potentially affecting each other. The device may be a DER device 128 installed in an energy system 130, such as an electrical system or grid of a customer, such as a utility provider. Additionally, or alternatively, by using configuration settings available in the configuration WS endpoint 120, multiple CTS runtime systems, similar to the CTS runtime system 104, may be deployed for multiple tenants and potentially targeting multiple utility servers. For accessing the CTS WS gateway 112, the CTS system 100 utilizes services of an existing identity server, such as an authentication server 132. If the authentication server 132 is not available, then certificate level security may be for a given environment based on provisioned certificates. The CTS system 100 may be operated by one or more processors (processors) 134 communicatively coupled to, and associated with, the CTS system 100. The processors 134 may be located in the cloud 106, in a local system connected to the CTS system 100, the energy system 130 of the customer, or any combination of the above. The processors 134 may also be included in a DER control 136, which may control or manage overall process associated with the CTS 110. Test data, such as history, status, readings, and responses associated with tests from the CTS 110, may be stored in a memory, such as a test result database 138, which may be included in, or coupled to, the CTS postgres database 108, or included in, or coupled to, the DER control 136. In this example, the test result database 138 is shown as a component of, or included in, the CTS postgres database 108.

The CTS system 100 may incorporate test session management functionalities for managing the overall test execution lifecycle including an initial setup, such as recording existing communication settings between a device, such as the DER device 128, and a utility server, such as the utility server 126 or a distributed energy resource management system (DERMS), before any tests begin. The CTS system 100 may then temporarily adjust communication frequency settings to a more efficient rate, for example, one minute, for the duration of the testing process. Once the tests are complete, the original communication settings may be automatically restored to ensure no disruption to normal operations. The test session management may manage test execution based on a device type of the device being tested, such as aggregator-controlled device and directly-connected device. A system-wide timeout setting may also be included. For example, if a test session concludes without explicitly changing the communication settings, the system-wide timeout setting feature may automatically restore the communication settings, thus preventing any accidental configuration issues.

The CTS system 100 may include one or more configurable test suites, such as the CTS. The configurable test suites may provide a structured approach for grouping related tests together and allow creating multiple test suites designed for different purposes, such as commissioning new devices, performing diagnostics, and/or conducting periodic compliance checks. The configurable test suites may offer flexibility by allowing administrators to add or remove specific tests from a configurable test suite as needed. Additionally, a configurable test suite may include a version control to track any changes made to a configuration of the test suite over time. Administrators may also have the ability to manually execute specific test suites and define whether the entire suite(s) should halt upon encountering a failed test (“stop-on-failure” behavior) or continue on to completion for a more comprehensive evaluation. The configurable test suites may also provide the ability to re-run only the failed tests within a particular test suite after an initial execution, which may significantly reduce the time required to conduct retests and pinpoint any lingering issues. The CTS system 100 may additionally accommodate combined test cases that may be executed on either aggregator-controlled devices or directly-connected devices.

The CTS system 100 may also include one or more pre-defined test suites encompassing various functionalities relevant to the lifecycle of Distributed Energy Resources (DERs) as described below. A client DER commissioning test may be targeted for installers of DER devices, and may verify the successful installation, configuration, and registration of a DER device, such as the DER device 128 installed in the energy system 130, with a utility server, such as the utility server 126, using the protocol of the client. Example functionalities of the client DER commissioning test may include: testing ability of the DER client to discover and connect to the utility server; verifying successful registration by exchanging data through messages of the DER client; ensuring the installer has configured the DER client correctly for communication with the utility server, proper outputs, and various settings; and validating the exchange of essential data points, such as device capabilities and operational status. An installed DER periodic compliance testing may be targeted for utility service providers and DER system owners/operators, and may verify the ongoing compliance of an installed DER system with regulatory requirements or contractual agreements. Example functionalities of the installed DER periodic compliance testing may include: performing periodic checks to ensure the DER system continues to operate within specified power output limits; verifying adherence to grid interconnection standards and regulations; validating data reporting requirements as mandated by regulatory bodies or utility contracts; and detecting potential deviations from compliance that may require corrective actions.

A post-installation DER trouble shooting diagnostic testing may be targeted for installers, maintenance personnel, and DER system owners/operators, and may diagnose issues with a DER system after installation. Example functionalities of the post-installation DER trouble shooting diagnostic testing may include: testing various aspects of operation of the DER system including power generation, communication, and control functions; identifying potential problems causing malfunctions or performance issues; pinpointing root causes of failures within the DER system or its connection to the grid; and providing valuable data for troubleshooting and repairing the DER system. An original equipment manufacturer (OEM) quality assurance conformance testing may be targeted for DER device manufacturers, and may verifying if a DER device manufactured by a specific OEM adheres to the complete set of processes of the particular utility customer. Example functionalities of the OEM quality assurance conformance testing may include: testing the ability of the DER device to participate in all message exchanges of the particular customer; verifying that the DER device adheres to data format specifications of the particular customer for various resources; ensuring the DER device interoperates seamlessly with utility systems using the protocol of the particular customer; and identifying any deviations from the standard of the particular customer that might require adjustments in the design or firmware of the DER device. These pre-defined test suites described above may offer a comprehensive approach to managing the DER lifecycle, from initial registration and quality assurance to troubleshooting and ongoing compliance verification functionality.

Building blocks of configurable test suites are pre-defined tests, each of which encapsulates a specific testing objective and is designed to follow a defined sequence of steps. These pre-defined tests may offer detailed information that may be used to troubleshoot any failures that may occur during the testing process. In some cases, pre-defined tests may allow for customization of certain parameters to enable more tailored evaluations for specific devices or scenarios. A pre-defined test may include certain elements as described below. A unique test identification (ID) and description may provide a clear identifier and explanation associated with the test for easy reference. A pre-condition checks may provide defined actions to verify specific device states or data points before test execution begins to help ensure that the device is in a suitable condition for testing and that the results will be accurate. A sequence of control commands may provide a list of commands for the particular customer sent to the device along with corresponding parameters instructing the device to perform specific actions or retrieve data. Wait times and durations may provide defined pauses between commands and test steps to allow the device sufficient time to process commands and respond. Expected data ranges and responses may provide, for each step within the test, acceptable ranges defined for the data expected to be received from the device and used to determine whether the test step has passed or failed. A status hook may provide a stream that describes the current progress of the test case.

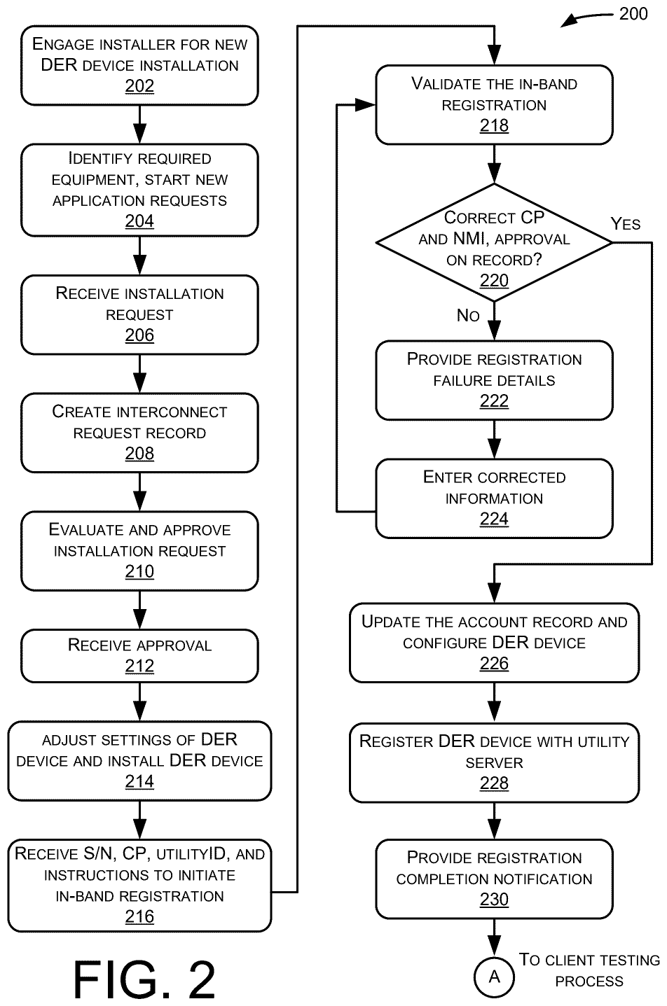

FIG. 2 illustrates a flowchart 200 of an example installation and commissioning of a DER device, such as the DER device 128. At block 202, a customer may engage an installer for installing a new DER device, such as the DER device 128, and the installer may identify required equipment and start new application requests at block 204. At block 206, an installer commissioning portal, which may be a component of the CTS UI 102, may receive the following information entered by the installer: installation request including a national meter identifier (NMI) of the DER device 128, account information of the installer, and DER information associated with the DER device 128. At block 208, a DERMS, or a utility back office, may create an interconnect request record based upon the installation request received by way of the installer commissioning portal, and evaluate and approve the installation request at block 210. At block 212, the CTS UI 102, by way of the installer commissioning portal, may provide, or notify the installer, the approval of the installation request, and the DER device 128 may receive setting adjustments and be installed in an electrical system, such as the energy system 130 of the customer, at block 214. At block 216, the installer may enter, and the CTS UI 102 may receive, by way of an OEM/aggregator server portal, DER device information, such as an NMI, a serial number (S/N), a connection point (CP), a utility identification (utilityID), and instructions to initiate an in-band registration of the DER device 128. The in-band registration refers to a circumstance in which the utility server 126 does not have a client long form device identifier (LFDI) created or whitelisted ahead of time, where the LFDI is a 20-byte hash of the IEEE 2030.5 certificate of the DER device 128 used for device access control.

At block 218, the utility server 126 may validate the in-band registration based on an identification of the DER device 128, such as the LFDI, and NMI, and provide the validation to the DERMS. For example, the utility server 126 may change its logic to allow registered aggregator-controlled device or directly-connected device to perform an in-band registration without whitelisting the LFDI. When new clients (aggregator-controlled devices and directly-connected devices) are added, the utility server 126 may create a device resource that does not have any topology connection and obtain a ConnectionPoint ID from the DER device 128 as part of the data exchange. At block 220, the DERMS may compare the ConnectionPoint ID against an approval record, such as an approved NMI list including the DER device 128 now validated, to confirm whether: 1) the CP is correct; and 2) there is an approval for the DER device 128. In response to determining that the CP is not correct or there is no approval at block 220 (“No” branch), the DERMS may provide registration failure details by way of the installer commissioning portal at block 222, and the installer may re-enter, and the CTS UI 102 may receive, by way of the OEM/aggregator server portal, corrected information at block 224. The process may then be repeated from block 218 as described above. Alternatively, in response to determining at block 220 that the CP is not correct or there is no approval, the DERMS may abandon the DER device 128 and the utility server 126 may delete the DER device 128 from the record.

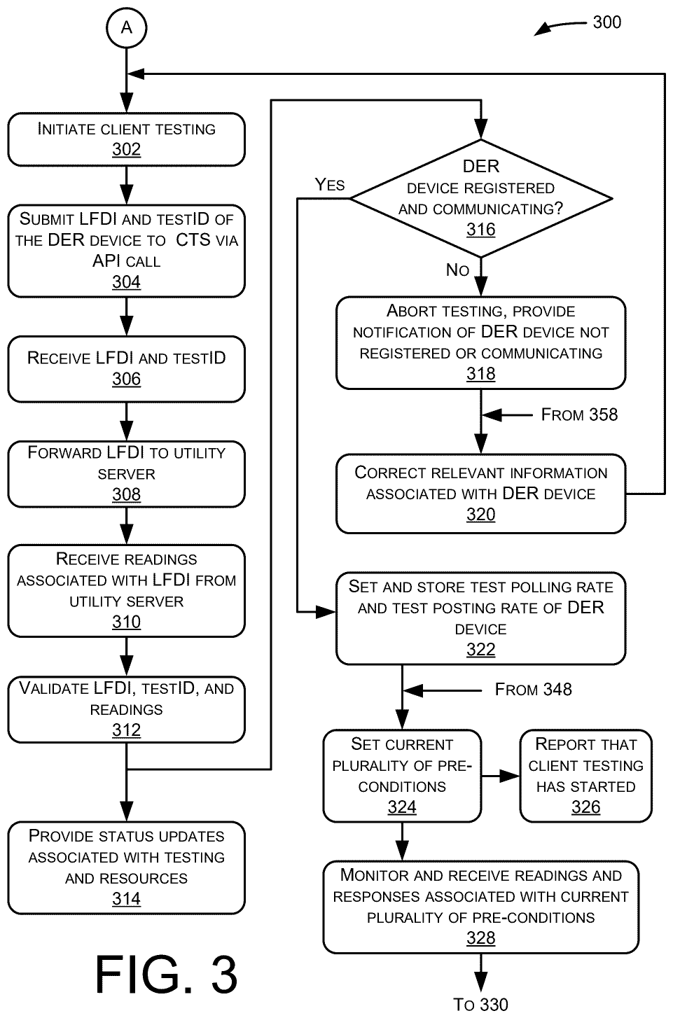

In response to determining that the CP is correct, i.e., the CP matches the approval record, and there is an approval at block 220 (“Yes” branch), the DERMS may update the account record and configure the DER device 128 at block 226, and the utility server 126 may register the DER device 128 at block 228. The CTS UI 102, by way of the installer commissioning portal, may provide a notification, such as a notification messaged display, of the registration completion at block 230. The process then proceeds to a client testing process (shown as A) as described with reference to FIGS. 3-5 below, which may be performed by a distributed energy management system (DEMS).

FIG. 3 illustrates a first portion of a flowchart 300 of an example process of testing an electrical device of a customer utilizing a client test suite (CTS), such as the CTS 110 designed for the client. At block 302, the installer may initiate the client testing, which may include one or more tests associated with the electrical device, such as the DER device 128 utilizing the CTS 110, and submit a test identification (testID) of the one or more tests and a long form device identifier (LFDI) associated with the DER device 128 installed in the energy system 130 of the customer, to the CTS 110 with an application programming interface (API) call using the installer commissioning portal at block 304. At block 306, the CTS 110 may receive the LFDI and the testID of the DER device 128, and forward the LFDI to the utility server 126 at block 308. By forwarding the LFDI to the utility server 126, the CTS 110 may cause the utility server 126 to compare the LFDI to LFDIs stored in the utility server 126. At block 310, the CTS 110 may receive, from the utility server 126, comparison results, or readings associated with the LFDI, and validate the LFDI, testID, and readings at block 312 based on the readings. The CTS 110 may additionally generate a CTS job number associated with the one or more tests, and provide the installer with status updates associated with the one or more tests and resources by way of the installer commissioning portal by having the installer subscribe to the CTS job number at block 314. Additionally, or alternatively, the CTS 110 may cause the test status report WS endpoint 122 of the CTS WS gateway 112 to generate the CTS job number and the status updates.

At block 316, the CTS may determine whether the DER device 128 is registered with the utility server 126 and communicating with the energy system 130 using protocol of the client. In response to determining that the DER device 128 is not registered with the utility server 126 or communicating with the energy system 130 using the protocol of the client (“No” branch) at block 316, the CTS 110 may abort the testing and provide a notification of the DER device 128 not being registered or communicating via the installer commissioning portal at block 318. At block 320, the installer may correct defects, such as incorrect information associated with the DER device 128, and the process may be repeated from block 302, where the installer may re-initiate the client testing. In response to determining that the DER device 128 is registered with the utility server 126 and communicating with the energy system 130 using the protocol of the client (“Yes” branch) at block 316, the CTS 110 may set, or cause the utility server 126 to set, a test polling rate and a test posting rate of the DER device 128 and store the test polling rate and the test posting rate at block 322. For example, the CTS 110 may utilize the configuration WS endpoint 120 to cause the utility server 126 to set the test polling rate and the test posting rate.

At block 324, the CTS 110 may set, or cause the utility server 126 to set by utilizing the configuration WS endpoint 120, a current plurality of pre-conditions associated with a current test of the client testing. That is, when the client testing is initiated, a first plurality of pre-conditions is set as the current plurality of pre-conditions and a first test, or a first suite, of the client testing is set as the current test, and if the client testing is not completed, the next (second, third, fourth, . . . ) plurality of pre-conditions is set as the current plurality and next test of the client testing is set as the current test, until the client testing is completed. Such queuing of the tests may be coordinated by utilizing the CTS execution WS endpoint 124 for execution into the distributed event streaming platform 114. The container orchestration system 116 may automatically read requests from the distributed event streaming platform 114 and execute the test, or the test suite, one at a time, queued in a defined order and using defined parameters.

The pre-conditions may include the DER device 128 being configured with uniform resource identifier (URI) information of the utility server 126, the DER device 128 having obtained necessary connection details, the DER device 128 having successfully registered with the utility server 126, etc. Additionally, the CTS 110 may cause the test status report WS endpoint 122 to indicate and/or report, for example, by displaying through the use of the installer commissioning portal, the job status that the client testing has started at block 326. The CTS 110 may monitor, and receive from the utility server 126, readings and responses associated with the first (current) plurality of pre-conditions at block 328.

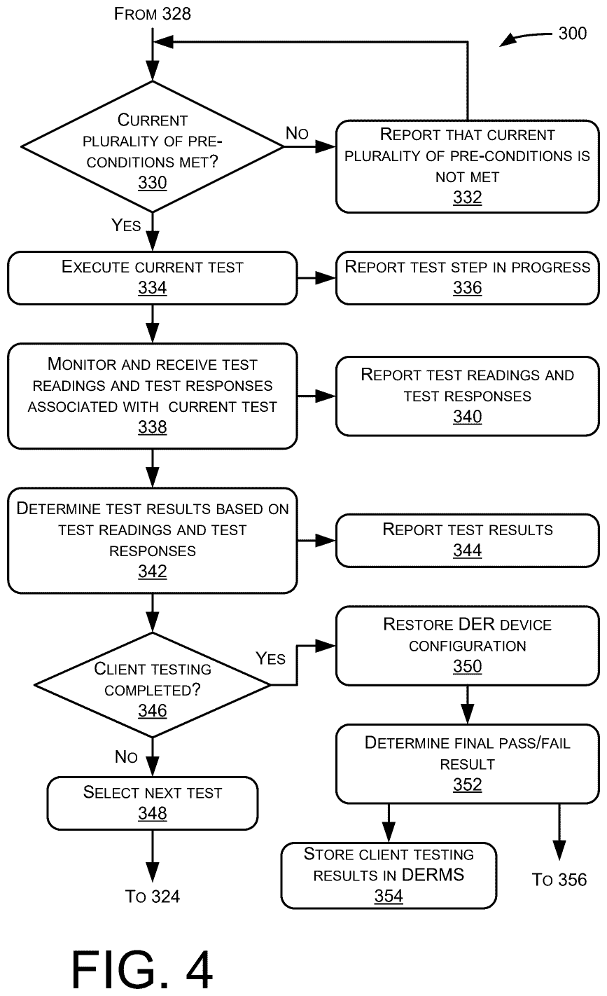

Referring to FIG. 4, which illustrates a second portion of the flowchart 300 continuing from FIG. 3, the CTS 110 may determine whether the first (current) plurality of pre-conditions is met based on the readings and responses from the utility server 126 at block 330. In response to determining that the first (current) plurality of pre-conditions is not met at block 330 (“No” branch), the CTS 110 may cause the test status report WS endpoint 122 to indicate and/or report, for example, by displaying through the use of the installer commissioning portal, the job status that the current plurality of pre-conditions is not met at block 332. The process may then loop back to block 330 to wait for the first (current) plurality of pre-conditions to be met. In response to determining that the first (current) plurality of pre-conditions is met at block 330 (“Yes” branch), the CTS 110 may execute, or cause utility server 126 to execute, by way of the CTS execution WS endpoint 124, the first (current) test at block 334. The CTS 110 may cause the test status report WS endpoint 122 to report, for example, by displaying through the use of the installer commissioning portal, the test step in progress at block 336. The CTS 110 may monitor, and receive from the utility server 126, test readings and test responses associated with the first (current) test at block 338, and the CTS 110 may cause the test status report WS endpoint 122 to report, for example, by displaying through the use of the installer commissioning portal, the readings and responses associated with the first (current) test at block 340.

At block 342, The CTS 110 may determine test results based on the test readings and test responses, and may cause the test status report WS endpoint 122 to report, for example, by displaying through the use of the installer commissioning portal, the test results at block 344. Test data, such as test history, the test results, test readings, and test responses may be stored in the test result database 138, for example, by way of the test status report WS endpoint 122. At block 346, the CTS 110 may determine whether the client testing has been completed, for example, by way of the test status report WS endpoint 122 or the CTS execution WS endpoint 124. In response to determining that the client testing has not been completed, the CTS 110, by way of the CTS execution WS endpoint 124 for example, may select the next test, such as the second test of the one or more tests of the client testing, as the current test, at block 348, and the process may be repeated from block 324. In response to determining that the client testing has been completed, the CTS 110, may cause, by way of the configuration WS endpoint 120, the utility server 126 to automatically restore the configuration of the DER device 128 at block 350. At block 352, the CTS 110 may determine, by way of the CTS execution WS endpoint 124, a final pass/fail result, and results from the client testing are stored in the DERMS at block 354.

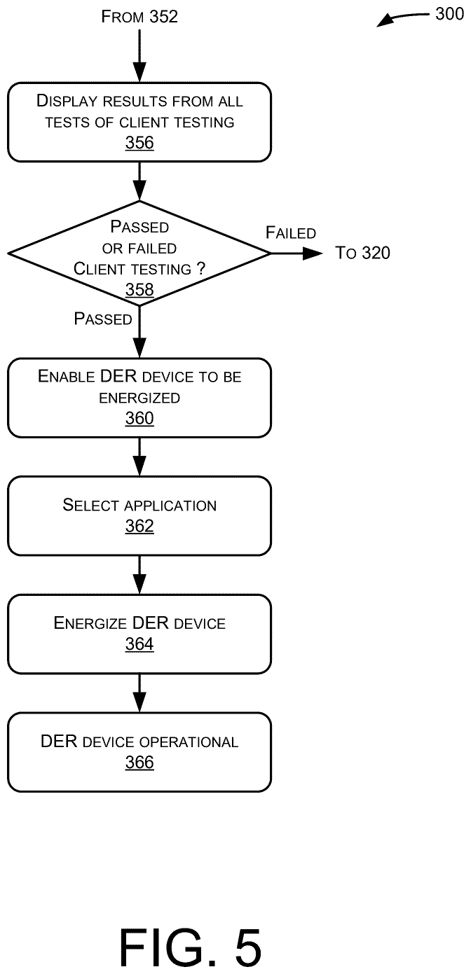

Referring to FIG. 5, which illustrates a third portion of the flowchart 300 continuing from FIG. 4, the CTS 110 may cause the CTS UI 102, by way of the test status report WS endpoint 122, to display the results from all tests of the one or more tests of the client testing at block 356. At block 358, if the DER device 128 has failed the client testing, the process may be repeated from block 320, where the installer may correct defects, such as incorrect information associated with the DER device 128, and the process may be repeated from block 302, where the installer may re-initiate the client testing. The DER device 128 may be prevented from being energized until passing the client testing. The test data stored in the test result database 138 may provide historical information associated with previous client tests that the DER device 128 has been through since the registration. The historical information may include, but not limited to, testIDs, job numbers, test descriptions, test suite names, versions, status (passed, canceled, or failed), a request date (date that the DER device 128 was added to the test queue), a start date (date the CTS testing was initiated for the DER device 128), a complete date (date that CTS 110 competed the test), a summary of the test results (pass/fail and details, such as measurements, from the CTS 110), and aging days (number of days since the previous test). The CTS system 100 may enable a user, such as the installer, to see the historical information, restart a test with a new job number and/or rerun failed tests. The CTS system 100 may also filter the historical information on test suite names, versions, status, and request/start/complete date ranges.

At block 358, if the DER device 128 has passed the client testing, the CTS 110 may enable the DER device 128 to be energized at block 360. The installer may select an application for the DER device 128 at block 362, and energize the DER device 128 at block 364. The DER device 128 may then be operational at block 366. The process described by the flowchart 300 with refence to FIGS. 3-5 above may be repeated periodically, for example, once a year, twice a year, or any appropriate period or time interval, to ensure that the DER device 128 continues to function properly.

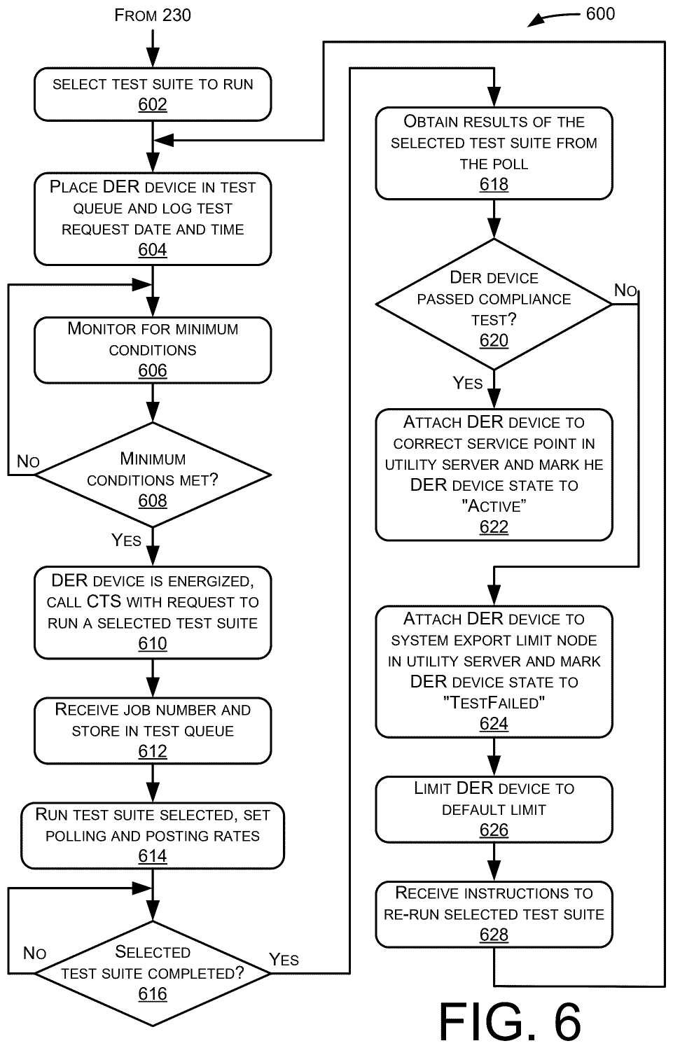

Alternatively, once the DER device 128 has passed the approval validation step after inspection as described above with referenced to FIG. 2, the DER control 136 may automatically perform the compliance testing of the DER device 128 similar to the process performed by the DEMS as described above with reference to FIGS. 3-5. However, because there can be an expected period (anywhere from one day to 14 days) between an installer completing the installation to the inspector performing the inspection and energizing the DER device 128, the compliance testing may not be started while the DER device 128 is offline and not energized. FIG. 6 illustrates a flowchart 600 of an example automatic testing process of DER device 128 of the customer utilizing the CTS 110.

Continuing from block 230 of FIG. 2, the DER control 136 may select a test suite, available from the CTS 110, to run based on a DER type of the DER device 128 at block 602, and put the DER device 128 into the test queue and log the test request date and time at block 604. Then, the DER control 136 may monitor for one or more preselected minimum thresholds, or minimum conditions, associated with the DER device 128 at block 606 before initiating the CTS compliance testing. That is, prior to monitoring for the preselected minimum condition/threshold, the registration of the DER device 128 with the utility server 126 is completed at block 228 and the notice of the registration completion is provided at block 230. The preselected minimum conditions/thresholds may include the following:
the DER device 128 being online and the DER control 136 communicating with, i.e., receiving information and readings from, the utility server 126;
DER readings from the DER device 128 meeting a minimum threshold output power, for example, for a solar power generator or an inverter coupled to the solar power generator, a greater of: 1) a preselected output power, such as 2,000 watts, or 2) output power exceeding 50% of a stated or rated output power; and
the DER device 128 not currently running a CTS test initiated by DER control 136.

The DER control 136 may determine whether the minimum conditions are met at block 608. In response to determining that the minimum conditions are not met (“No” branch), the process may loop back to block 606 where the DER control 136 may continue monitoring for the minimum conditions. In response to determining that the minimum conditions are met (“Yes” branch), the DER control 136 may determine that the DER device 128 is energized, and call the CTS 110, by way of the API call, with a request, or post the request, to create a job to run the selected test suite against the DER device 128 at block 610. The selected test suite may include one or more tests to run against the DER device 128. In response to receiving the request, the CTS 110 may respond back to the DER control 136 with a job number associated with, or corresponding to, the selected test suite if the request is accepted, and the DER control 136 may receive the job number and store in the test queue at block 612. The DER control 136 may then run the test suite selected and set a polling rate and a posting rate at block 614. The DER control 136 may periodically poll the CTS 110 for a job status of the selected test suite including results from tests completed at the time polling and determine whether the selected test suite has been completed by the CTS 110 at block 616. In response to determining that the selected test suite has not been completed (“No” branch), the process may loop back to block 616 where the DER control 136 may continue periodically polling the CTS for the job status. In response to determining that the selected test suite has been completed (“Yes” branch), the DER control 136 may obtain results of the selected test suite from the poll at block 618, and determine whether the DER device 128 passed the compliance test, i.e., the selected test suite from the CTS 110, at block 620. The DER control 136 may store test data, such as test history, the test results, test readings, and test responses in the test result database 138, for example, by way of the test status report WS endpoint 122.

In response to determining that the DER device 128 passed the compliance test, the DER control 136 may attach the DER device 128 to a correct service point in a topology structure in the utility server 126 and mark the DER device state of the DER device 128 to “Active” at block 622. A service point is a physical location where a DER device, such as the DER device 128, is installed and connected to an energy system, such as the energy system 130, usually for the purpose of delivering electric service to a utility customer. The topology structure may be provided by a Geographic Information System (GIS) of the utility provider, and the DERMS may synchronize the topology structure into a software of a utility server, such as the utility server 126. In response to determining that the DER device 128 did not pass the compliance test, the DER control 136 may attach the DER device 128 to a system export limit node in the utility server 126 and mark the DER device state to “TestFailed” at block 624. At block 626, the DER control 136 may limit the DER device 128 that failed to a default limit, for example, to 500 W at block 626. The DER control 136 may re-run the selected test suite based on receiving instructions from an administrator at block 628, and the process may loop back to block 604. The test data stored in the test result database 138 may provide historical information associated with previous client tests that the DER device 128 has been through since the registration. The historical information may include, but not limited to, testIDs, job numbers, test descriptions, test suite names, versions, status (passed, canceled, or failed), a request date (date that the DER device 128 was added to the test queue), a start date (date the CTS testing was initiated for the DER device 128), a complete date (date that CTS 110 competed the test), a summary of the test results (pass/fail and details, such as measurements, from the CTS 110), and aging days (number of days since the previous test). The DER control 136 may enable a user, such as the administrator, to see the historical information, restart a test with a new a job number, and/or rerun failed tests. The DER control 136 may also filter the historical information on test suite names, versions, status, and request/start/complete date ranges.

The process described by the flowchart 600 with refence to FIG. 6 above may be repeated periodically, for example, once a year, to ensure that the DER device 128 continues to function properly.

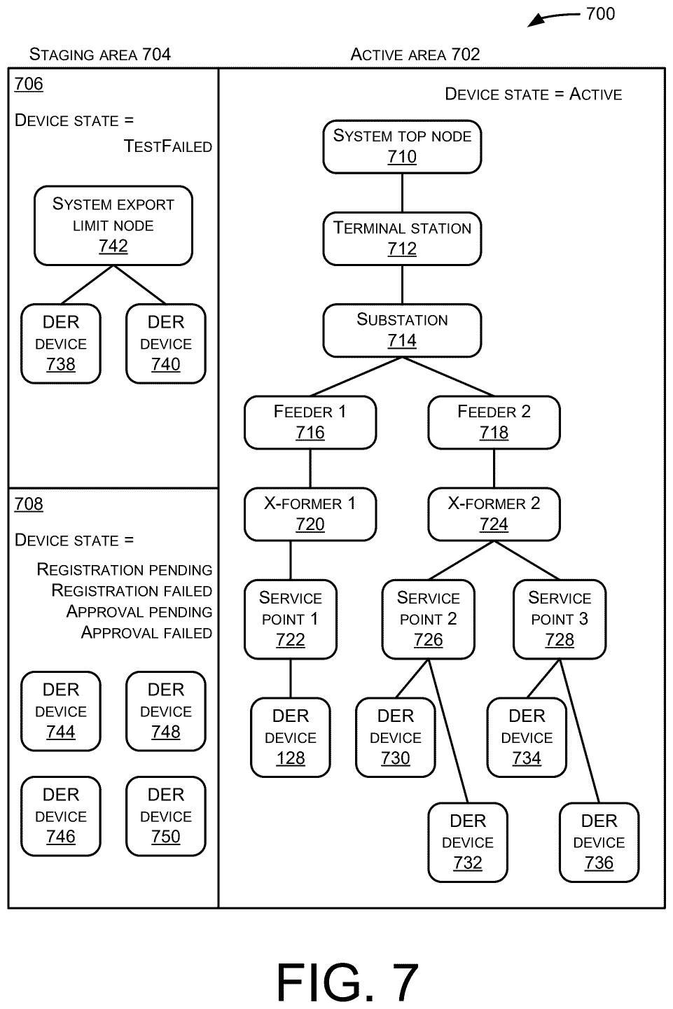

FIG. 7 illustrates an example topology structure 700 provided by a utility server, such as the utility server 126 of the CTS system 100. As described above, the utility server 126 may be associated with the DER device 128 and the energy system 130, and the topology structure may represent a logical or virtual topology of at least a portion of the energy system 130 and a location or association of the DER device 128 within the topology structure. The topology structure 700 may include an active area 702 and a staging area 704 having a first staging area 706 and a second staging area 708.

The active area 702 includes a topology of active components of an energy system, such as the energy system 130, and a DER device that has passed the compliance test with the device state of “Active,” such as the DER device 128 from block 622 described above with reference to FIG. 6. In this example, the active components shown include a system top node 710, a terminal station 712 connected to the system top node 710, and a substation 714 connected to the terminal station 712. The substation 714 may connect to one or more feeders, such as a first feeder 716 and a second feeder 718. The first feeder 716 may connect to a first transformer 720 that connects to a first service point 722, where the DER device 128 may be attached as an active device. The second feeder 718 may connect to a second transformer 724 that connects to one or more service points, such as a second service point 726 and a third service point 728, each of which may connect to one or more active devices, such as DER devices 730 and 732 connected to the second service point 726 and DER devices 734 and 736 connected to the third service point 728.

The first staging area 706 may hold DER devices that failed the compliance test and having the device state of “TestFailed.” In this example, two DER devices 738 and 740, having failed the compliance test, are held in the first staging area 706 and attached to a limited node 742, which may limit outputs of the failed devices to a default limit, for example, to 500 W as described above with reference to FIG. 6. Keeping the failed devices in the limited output state ensures that the grid stability is not jeopardized by the failed devices. The second staging area 708 may hold DER devices having the device state of “Registration pending,” “Registration failed,” “Approval pending,” and “Approval failed.” In this example, four DER devices 744, 746, 748, and 750 are shown as each having one of the device states of “Registration pending,” “Registration failed,” “Approval pending,” and “Approval failed.”

Some or all operations of the methods described above can be performed by execution of computer-readable instructions stored on a computer-readable storage medium, as defined below. The terms “computer-readable medium,” “computer-readable instructions,” “computer-executable instructions,” and “processor-executable instructions” as used in the description and claims, include routines, applications, application modules, program modules, programs, components, data structures, algorithms, and the like. Computer-readable and-executable instructions and processor-executable instructions can be implemented on various system configurations, including single-processor or multiprocessor systems, minicomputers, mainframe computers, personal computers, hand-held computing devices, microprocessor-based, programmable consumer electronics, combinations thereof, and the like.

The computer-readable storage media may include volatile memory (such as random-access memory (RAM)) and/or non-volatile memory (such as read-only memory (ROM), flash memory, etc.). The computer-readable storage media may also include additional removable storage and/or non-removable storage including, but not limited to, flash memory, magnetic storage, optical storage, and/or tape storage that may provide non-volatile storage of computer-readable instructions, data structures, program modules, and the like.

A non-transitory computer-readable storage medium is an example of computer-readable media. Computer-readable media includes at least two types of computer-readable media, namely computer-readable storage media and communications media. Computer-readable storage media includes volatile and non-volatile, removable and non-removable media implemented in any process or technology for storage of information such as computer-readable instructions, data structures, program modules, or other data. Computer-readable storage media includes, but is not limited to, phase change memory (PRAM), static random-access memory (SRAM), dynamic random-access memory (DRAM), other types of random-access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transmission medium that can be used to store information for access by a computing device. In contrast, communication media may embody computer-readable instructions, data structures, program modules, or other data in a modulated data signal, such as a carrier wave, or other transmission mechanism. As defined herein, computer-readable storage media do not include communication media.

The computer-readable instructions, such as the CTS 110, stored on one or more non-transitory computer-readable storage media, such as the CTS postgres database 108, when executed by one or more processors, such as the processors 134, may perform operations described above with reference to FIGS. 1-7. Generally, computer-readable instructions include routines, programs, objects, components, data structures, and the like that perform particular functions or implement particular abstract data types. The order in which the operations are described is not intended to be construed as a limitation, and any number of the described operations can be combined in any order and/or in parallel to implement the processes.

### EXAMPLE CLAUSES

A. A method for testing an electrical device installed in an energy system, the method including: selecting a test suite to run against the electrical device based on a type of the electrical device; monitoring for an output power of the electrical device; determining whether the output power of the electrical device is greater than a preselected minimum threshold; in response to determining that the output power of the electrical device is greater than a preselected minimum threshold: determining that the electrical device is energized and running the test suite selected; determining whether the electrical device has passed the test suite selected; in response to determining that the electrical device has passed the test suite selected: attaching the electrical device to a designated service point in a topology structure provided by a utility server associated with the electrical device and the energy system, marking a state of the electrical device to active, and activating the electrical device to perform in the energy system; and in response to determining that the electrical device has not passed the test suite selected: attaching the electrical device to a limited node in the topology structure and limiting the electrical device to function within a default control limit.
B. The method of example A, further including: periodically repeating the testing of the electrical device installed in the energy system according to example A.
C. The method of example A, wherein the preselected minimum threshold includes the electrical device being online and communicating with a utility server associated with the electrical device.
D. The method of example A, wherein the preselected minimum threshold includes the output power of the electrical device exceeding a greater of: a preselected output power of the electrical device, or 50% of a rated power output of the electrical device.
E. The method of example A, wherein selecting the test suite to run includes selecting the test suite from a client test suite (CTS) designed for the electrical device installed in an electrical system of a utility provider.
F. The method of example E, wherein running the test suite selected includes: posting a request to the CTS to create a job to run the test suite selected; receiving a job number corresponding to the test suite selected from the CTS; storing the job number in a test queue; and periodically polling the CTS for a result of the test suite selected.
G. The method of example A, wherein the electrical device is a distributed energy resource (DER) device.
H. The method of example G, wherein the electrical device is an inverter coupled to a solar power generator.
I. One or more computer-readable media storing computer-readable instructions that, when executed by one or more processors associated with a system for testing an electrical device installed in an energy system, cause the one or more processors to perform operations, the operations comprising: selecting a test suite to run against the electrical device based on a type of the electrical device; monitoring for an output power of the electrical device; determining whether the output power of the electrical device is greater than a preselected minimum threshold; in response to determining that the output power of the electrical device is greater than a preselected minimum threshold: determining that the electrical device is energized and running the test suite selected; determining whether the electrical device has passed the test suite selected; in response to determining that the electrical device has passed the test suite selected: attaching the electrical device to a designated service point in a topology structure provided by a utility server associated with the electrical device and the energy system, marking a state of the electrical device to active, and activating the electrical device to perform in the energy system; and in response to determining that the electrical device has not passed the test suite selected: attaching the electrical device to a limited node in the topology structure and limiting the electrical device to function within a default control limit.
J. The one or more computer-readable media of example I, wherein the preselected minimum threshold includes the electrical device being online and communicating with a utility server associated with the electrical device.
K. The one or more computer-readable media of example I, wherein the preselected minimum threshold includes the output power of the electrical device exceeding a greater of: a preselected output power of the electrical device or 50% of a rated power output of the electrical device.
L. The one or more computer-readable media of example I, wherein selecting the test suite to run includes selecting the test suite from a client test suite (CTS) designed for the electrical device installed in an electrical system of a utility provider.
M. The one or more computer-readable media of example L, wherein running the test suite selected includes: posting a request to the CTS to create a job to run the test suite selected; receiving a job number corresponding to the test suite selected from the CTS; storing the job number in a test queue; and periodically polling the CTS for a result of the test suite selected.
N. The one or more computer-readable media of example I, wherein the electrical device is a distributed energy resource (DER) device.
O. The one or more computer-readable media of example N, wherein the electrical device is an inverter coupled to a solar power generator.
P. An electrical device testing system including: one or more processors and one or more computer-readable media communicatively coupled to the one or more processors, the one or more computer-readable media storing computer-readable instructions that, when executed by the one or more processors, cause the one or more processors to perform operations, the operations including: selecting a test suite to run against an electrical device installed in an energy system based on a type of the electrical device; monitoring for an output power of the electrical device; determining whether the output power of the electrical device is greater than a preselected minimum threshold; in response to determining that the output power of the electrical device is greater than a preselected minimum threshold: determining that the electrical device is energized and running the test suite selected; determining whether the electrical device has passed the test suite selected; in response to determining that the electrical device has passed the test suite selected: attaching the electrical device to a designated service point in a topology structure provided by a utility server associated with the electrical device and the energy system, marking a state of the electrical device to active, and activating the electrical device to perform in the energy system; and in response to determining that the electrical device has not passed the test suite selected: attaching the electrical device to a limited node in the topology structure, and limiting the electrical device to function within a default control limit.
Q. The electrical device testing system of example P, wherein the preselected minimum threshold includes the electrical device being online and communicating with a utility server associated with the electrical device.
R. The electrical device testing system of example P, wherein the preselected minimum threshold includes the output power of the electrical device exceeding a greater of a preselected output power of the electrical device or 50% of a rated power output of the electrical device.
S. The electrical device testing system of example P, wherein selecting the test suite to run includes selecting the test suite from a client test suite (CTS) designed for the electrical device installed in an electrical system of a utility provider.
T. The electrical device testing system of example P, wherein the electrical device is a distributed energy resource (DER) device.

### CONCLUSION

Although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims.

What is claimed is:

1. A method for testing an electrical device installed in an energy system, the method comprising:
selecting a test suite to run against the electrical device based on a type of the electrical device;
monitoring for an output power of the electrical device;
determining whether the output power of the electrical device is greater than a preselected minimum threshold;
in response to determining that the output power of the electrical device is greater than a preselected minimum threshold:
determining that the electrical device is energized, and
running the test suite selected;
determining whether the electrical device has passed the test suite selected;
in response to determining that the electrical device has passed the test suite selected:
attaching the electrical device to a designated service point in a topology structure provided by a utility server associated with the electrical device and the energy system,
marking a state of the electrical device to active, and
activating the electrical device to perform in the energy system; and
in response to determining that the electrical device has not passed the test suite selected:
attaching the electrical device to a limited node in the topology structure, and
limiting the electrical device to function within a default control limit.

2. The method of claim 1, further comprising:
periodically repeating the testing of the electrical device installed in the energy system according to claim 1.

3. The method of claim 1, wherein the preselected minimum threshold includes the electrical device being online and communicating with a utility server associated with the electrical device.

4. The method of claim 1, wherein the preselected minimum threshold includes the output power of the electrical device exceeding a greater of:
a preselected output power of the electrical device, or
50% of a rated power output of the electrical device.

5. The method of claim 1, wherein selecting the test suite to run includes:
selecting the test suite from a client test suite (CTS) designed for the electrical device installed in an electrical system of a utility provider.

6. The method of claim 5, wherein running the test suite selected includes:
posting a request to the CTS to create a job to run the test suite selected;
receiving a job number corresponding to the test suite selected from the CTS;
storing the job number in a test queue; and
periodically polling the CTS for a result of the test suite selected.

7. The method of claim 1, wherein the electrical device is a distributed energy resource (DER) device.

8. The method of claim 7, wherein the electrical device is an inverter coupled to a solar power generator.

9. One or more computer-readable media storing computer-readable instructions that, when executed by one or more processors associated with a system for testing an electrical device installed in an energy system, cause the one or more processors to perform operations, the operations comprising:
selecting a test suite to run against the electrical device based on a type of the electrical device;
monitoring for an output power of the electrical device;
determining whether the output power of the electrical device is greater than a preselected minimum threshold;
in response to determining that the output power of the electrical device is greater than a preselected minimum threshold:
determining that the electrical device is energized, and
running the test suite selected;
determining whether the electrical device has passed the test suite selected;
in response to determining that the electrical device has passed the test suite selected:
attaching the electrical device to a designated service point in a topology structure provided by a utility server associated with the electrical device and the energy system,
marking a state of the electrical device to active, and
activating the electrical device to perform in the energy system; and
in response to determining that the electrical device has not passed the test suite selected:
attaching the electrical device to a limited node in the topology structure, and
limiting the electrical device to function within a default control limit.

10. The one or more computer-readable media of claim 9, wherein the preselected minimum threshold includes the electrical device being online and communicating with a utility server associated with the electrical device.

11. The one or more computer-readable media of claim 9, wherein the preselected minimum threshold includes the output power of the electrical device exceeding a greater of:
a preselected output power of the electrical device, or
50% of a rated power output of the electrical device.

12. The one or more computer-readable media of claim 9, wherein selecting the test suite to run includes:
selecting the test suite from a client test suite (CTS) designed for the electrical device installed in an electrical system of a utility provider.

13. The one or more computer-readable media of claim 12, wherein running the test suite selected includes:
posting a request to the CTS to create a job to run the test suite selected;
receiving a job number corresponding to the test suite selected from the CTS;
storing the job number in a test queue; and
periodically polling the CTS for a result of the test suite selected.

14. The one or more computer-readable media of claim 9, wherein the electrical device is a distributed energy resource (DER) device.

15. The one or more computer-readable media of claim 14, wherein the electrical device is an inverter coupled to a solar power generator.

16. An electrical device testing system comprising:
one or more processors; and
one or more computer-readable media communicatively coupled to the one or more processors, the one or more computer-readable media storing computer-readable instructions that, when executed by the one or more processors, cause the one or more processors to perform operations, the operations comprising:
selecting a test suite to run against an electrical device installed in an energy system based on a type of the electrical device;
monitoring for an output power of the electrical device;
determining whether the output power of the electrical device is greater than a preselected minimum threshold;
in response to determining that the output power of the electrical device is greater than a preselected minimum threshold:
determining that the electrical device is energized, and
running the test suite selected;
determining whether the electrical device has passed the test suite selected;
in response to determining that the electrical device has passed the test suite selected:
attaching the electrical device to a designated service point in a topology structure provided by a utility server associated with the electrical device and the energy system,
marking a state of the electrical device to active, and
activating the electrical device to perform in the energy system; and
in response to determining that the electrical device has not passed the test suite selected:
attaching the electrical device to a limited node in the topology structure, and
limiting the electrical device to function within a default control limit.

17. The electrical device testing system of claim 16, wherein the preselected minimum threshold includes the electrical device being online and communicating with a utility server associated with the electrical device.

18. The electrical device testing system of claim 16, wherein the preselected minimum threshold includes the output power of the electrical device exceeding a greater of:
a preselected output power of the electrical device, or
50% of a rated power output of the electrical device.

19. The electrical device testing system of claim 16, wherein selecting the test suite to run includes:
selecting the test suite from a client test suite (CTS) designed for the electrical device installed in an electrical system of a utility provider.

20. The electrical device testing system of claim 16, wherein the electrical device is a distributed energy resource (DER) device.
